(19) United States
(12) Patent Application Publication
(10) Pub. No.: US 2012/0133257 A1
(43) Pub. Date: May 31, 2012

(54) SIDE PLATE ASSEMBLY FOR A DEVICE CASING

(75) Inventors: CHIH-HUA CHEN, Tu-Cheng (TW); CHIA-WEN TSAI, Tu-Cheng (TW); CHIH-WEI KE, Tu-Cheng (TW)

(73) Assignee: HON HAI PRECISION INDUSTRY CO., LTD., Tu-Cheng (TW)

(21) Appl. No.: 12/978,625

(22) Filed: Dec. 26, 2010

(30) Foreign Application Priority Data
Nov. 29, 2010 (TW) 99141312

(51) Int. Cl. H05K 5/02

(52) U.S. Cl. 312/312

(57) ABSTRACT

An exemplary side plate assembly includes a side plate and an elongated reinforcing member. The side plate includes a main portion and two mounting portions at two opposite sides of the main portion. The reinforcing member is arranged at a middle of a side of the side plate. Two ends of the reinforcing member are respectively connected to the two mounting portions of the side plate. An inner side of the reinforcing member abuts the main portion of the side plate.

### BACKGROUND

1. Technical Field

The disclosure generally relates to casings of electronic devices, and more particularly to a side plate assembly used in a casing.

2. Description of Related Art

An electronic device, such as a computer or a server, usually includes a casing for accommodating components of the electronic device. The components typically include a central processing unit (CPU), a circuit board, a hard disk drive and an optical disk drive. The casing includes a cage, and two side plates mounted at two opposite lateral sides of the cage. Each side plate is made of a thin metal sheet. When the electronic device is in operation, the components of the electronic device such as the hard disk drive or the optical disk drive can cause the side plate to vibrate, generating unwanted noise.

What is needed, therefore, is a side plate assembly to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead placed upon clearly illustrating the principles of the present embodiments. Moreover, in the drawings, like reference numerals designate corresponding parts throughout the views.

FIG. 1 is an assembled, isometric view of a side plate assembly in accordance with an exemplary embodiment of the present disclosure.

FIG. 2 is an exploded view of the side plate assembly of FIG. 1.

FIG. 3 is an enlarged, isometric view of a reinforcing member of the side plate assembly of FIG. 1.

FIG. 4 is an enlarged view of a circled portion IV of FIG. 2.

FIG. 5 is an enlarged view of a circled portion V of FIG. 3.

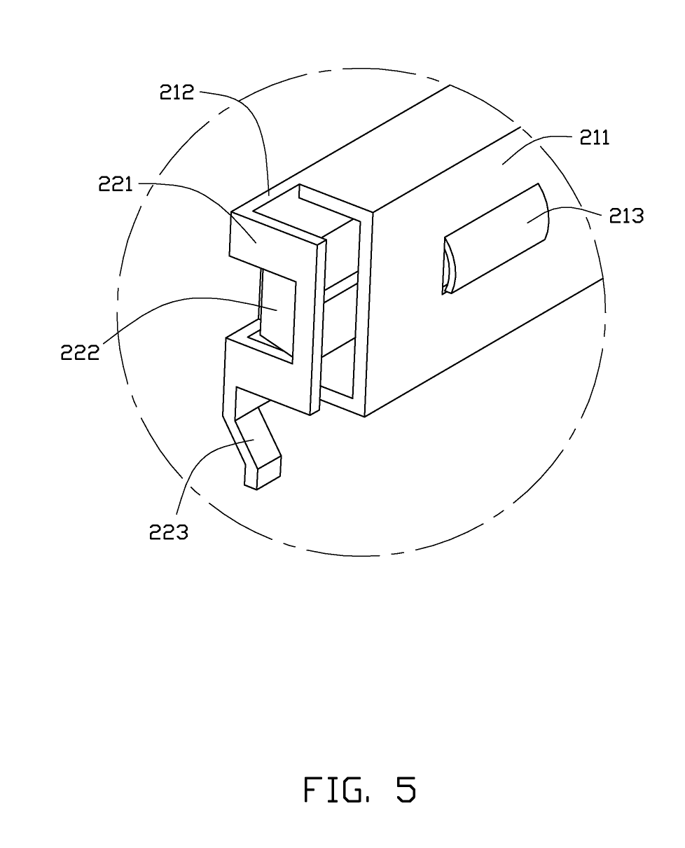

### DETAILED DESCRIPTION

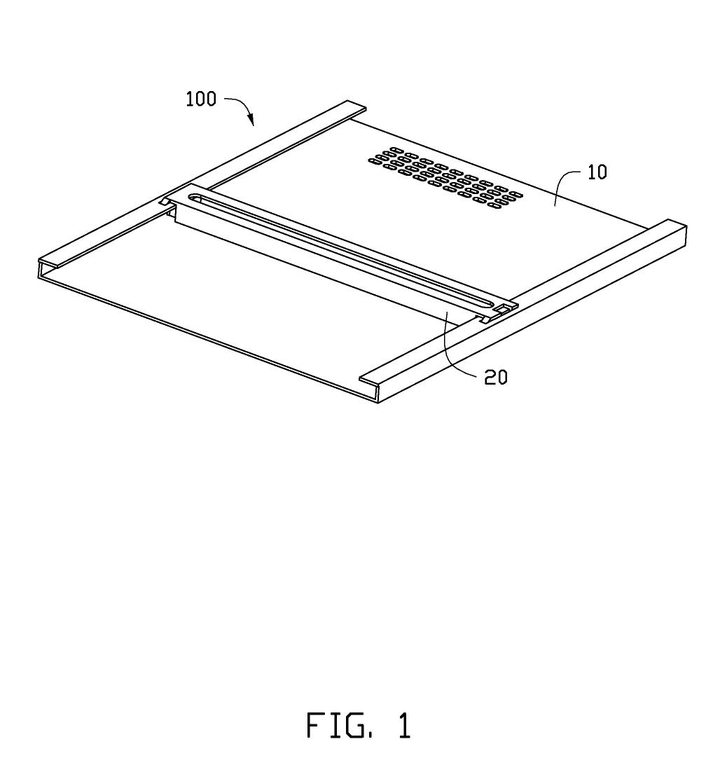

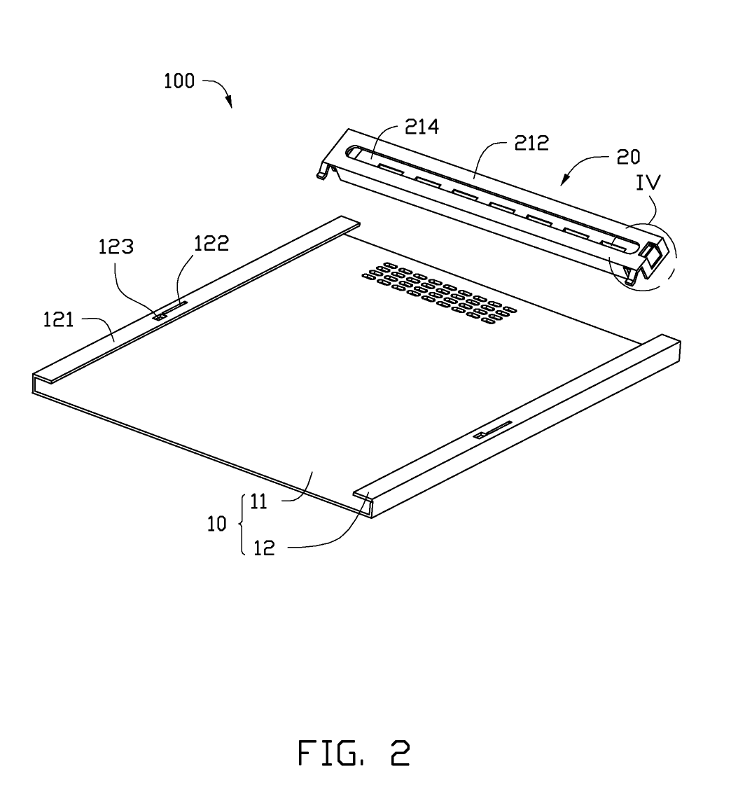

Referring to FIGS. 1-2, a side plate assembly 100 according to an exemplary embodiment of the present disclosure is shown. The side plate assembly 100 is used in a casing of an electronic device such as a computer or a server. The side plate assembly 100 is detachedly mounted at a lateral side of the casing for protecting components of the electronic device. The components typically include a CPU, a circuit board, a hard disk drive and an optical disk drive. The side plate assembly 100 includes a side plate 10 and a reinforcing member 20.

The side plate 10 includes a rectangular flat main portion 11, and two mounting portions 12 at two opposite sides of the main portion 11. Each mounting portion 12 is L-shaped, and has a flange 121 parallel to the main portion 11. The flange 121 defines an elongated through hole 122 in a middle thereof. The flange 121 further defines a rectangular positioning hole 123 therein adjacent to the through hole 122. The reinforcing member 20 is arranged at a middle of a side of the side plate 10. Two ends of the reinforcing member 20 are connected to the two mounting portions 12 of the side plate 10, respectively. An inner side of the reinforcing member 20 abuts the main portion 11 of the side plate 10.

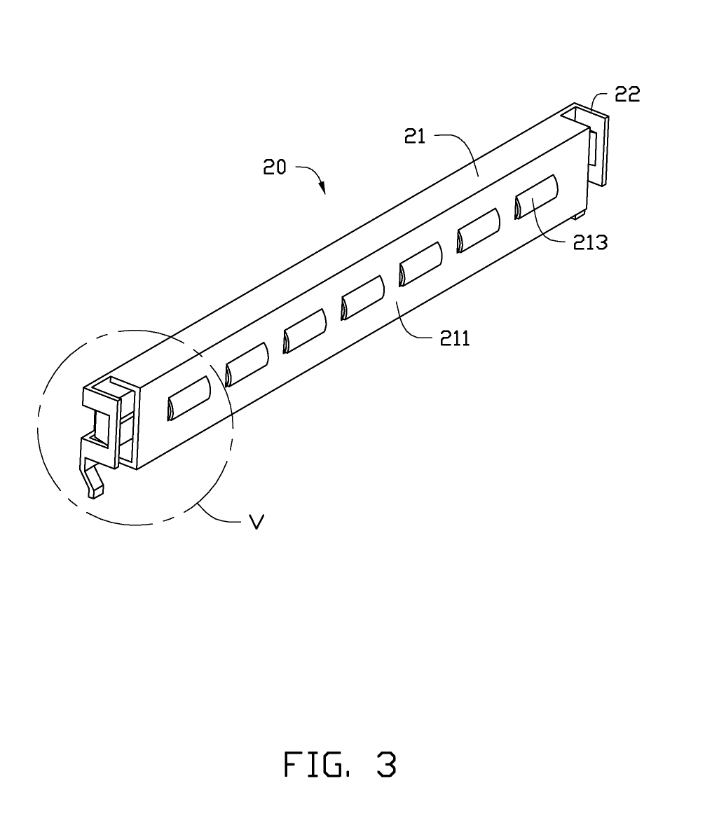

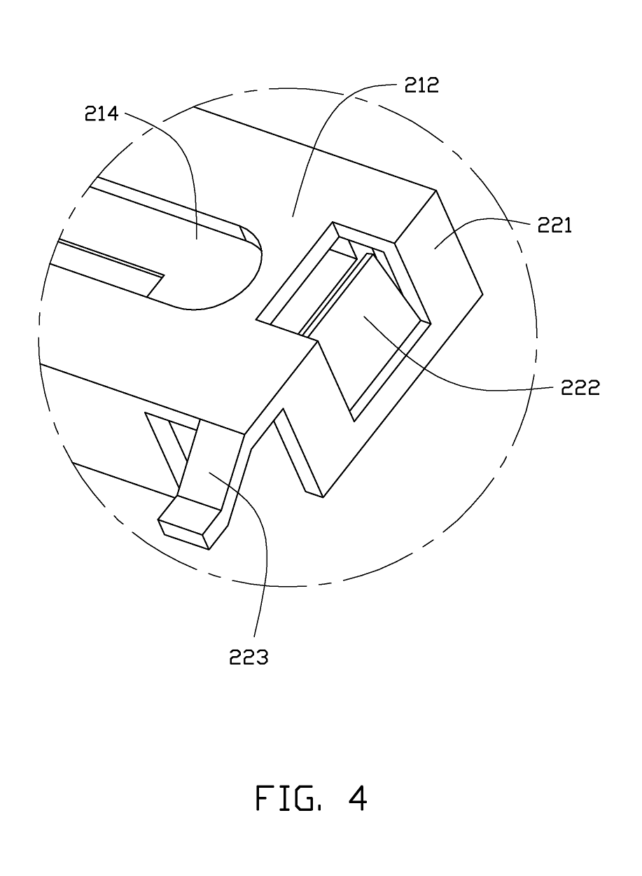

Referring also the FIGS. 3-4, the reinforcing member 20 is elongated. The reinforcing member 20 includes an elongated main body 21, and two clasping portions 22 at two opposite ends of the main body 21. The reinforcing member 20 can be stamped from metal sheet.

The main body 21 has a substantially hollow rectangular cross section. The main body 21 includes a bottom plate 211 facing the main portion 11 of the side plate 10, and a top plate 212 opposite to the bottom plate 211. A resilient element is provided between the bottom plate 211 of the main body 21 and the main portion 11 of the side plate 10, to enhance the pressing force therebetween. In this embodiment, the resilient element includes a plurality of resilient sheets 213 arranged along a longitudinal axis of the reinforcing member 20 and evenly spaced from each other. The resilient sheets 213 are integrally formed with the reinforcing member 20 as a single monolithic piece. The resilient sheets 213 protrude from the bottom plate 211 of the main body 21 towards the main portion 11 of the side plate 10. Each resilient sheet 213 is curved, and has a side connected to the bottom plate 211 of the main body 21. The top plate 212 defines an elongated opening 214 therein along the longitudinal axis of the reinforcing member 20.

Each clasping portion 22 includes a leg 221 extending from an end of the top plate 212 towards the bottom plate 211. The leg 221 forms a hook 222 thereon. The reinforcing member 20 forms two positioning pieces 223 thereon, corresponding to the positioning holes 123 of the two mounting portions 12 of the side plate 10. Each positioning piece 223 depends outwardly from a lateral side of the top plate 212 of the main body 21 at a position adjacent to a corresponding clasping portion 22.

In assembly, the two positioning pieces 223 of the reinforcing member 20 are received in the positioning holes 123 of the two mounting portions 12 of the side plate 10, respectively. The reinforcing member 20 is pressed downwardly towards the side plate 10, causing the clasping portions 22 to enter the through holes 122 and descend. The latching hooks 222 of the two clasping portions 22 contract when compressed in the through holes 122 of the two mounting portions 12, and then rebound to abut bottom surfaces of the flanges 121 after they pass through the through holes 122. Thus, the reinforcing member 20 is connected to the side plate 10 by the clasping portions 22 latching the mounting portions 12. The resilient sheets 213 are compressed to enhance force between the bottom plate 211 of the main body 21 and the main portion 11 of the side plate 10.

In the side plate assembly 100, the side plate 10 is reinforced by providing the reinforcing member 20 at one side of the side plate 10. When the side plate assembly 100 is used in a casing of an electronic device, vibration transmitted to the side plate 10 from components of the electronic device such as a hard disk drive or an optical disk drive is depressed or even eliminated altogether. Therefore the electronic device is apt to have minimal operating noise. In addition, the reinforcing member 20 is connected to the side plate 10 via the two clasping portions 22 buckled with the two mounting portions 12, respectively. Thus, the side plate assembly 100 is simply assembled.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A side plate assembly comprising:
a side plate comprising a main portion and two mounting portions at two opposite sides of the main portion; and
an elongated reinforcing member arranged at a middle of a side of the side plate, two ends of the reinforcing member being respectively connected to the two mounting portions of the side plate, an inner side of the reinforcing member abutting the main portion of the side plate.

2. The side plate assembly of claim 1, wherein the reinforcing member comprises an elongated main body and two clasping portions at two opposite ends of the main body, the reinforcing member being connected to the side plate via the two clasping portions buckled with the two mounting portions, respectively.

3. The side plate assembly of claim 2, wherein each of the two clasping portions comprises a leg extending from an end of the main body towards the main portion of the side plate, the leg forming a hook thereon, each of the two mounting portions defining a through hole therein, the leg of each of the two clasping portions being inserted in the through hole of a corresponding mounting portion, the hook of the leg extending through the through hole from one side of the mounting portion and abutting the other side of the mounting portion.

4. The side plate assembly of claim 3, wherein each of the two mounting portions is L-shaped, and has a flange parallel to the main portion, the through hole being defined in the flange.

5. The side plate assembly of claim 4, wherein the reinforcing member forms two positioning pieces on a lateral side of the main body respectively adjacent to the two clasping portions, the flange of each of the two mounting portions defining a positioning hole therein adjacent to the through hole, the two positioning pieces being received in the positioning holes of the two mounting portions, respectively.

6. The side plate assembly of claim 2, further comprising at least one resilient element compressed between the main body of the reinforcing member and the main portion of the side plate.

7. The side plate assembly of claim 6, wherein the at least one resilient element comprises a plurality of resilient sheets arranged along a longitudinal axis of the reinforcing member and spaced from each other.

8. The side plate assembly of claim 7, wherein the main body of the reinforcing member has a substantially hollow rectangular cross section, the main body having a bottom plate facing the main portion of the side plate, the resilient sheets being integrally formed with the reinforcing member as a single piece, each resilient sheet protruding from the bottom plate of the main body towards the main portion of the side plate.

9. The side plate assembly of claim 8, wherein each resilient sheet is curved, and has a side connected to the bottom plate of the main body.

10. The side plate assembly of claim 8, wherein the main body further has a top plate opposite to the bottom plate, each of the two clasping portions comprising a leg extending from an end of the top plate of the main body towards the main portion of the side plate, the leg forming a hook thereon, each of the two mounting portions defining a through hole therein, the leg of each of the two clasping portions being inserted in the through hole of a corresponding mounting portion, the hook of the leg extending through the through hole from one side of the mounting portion and abutting the other side of the mounting portion.

11. A side plate assembly comprising:
a side plate comprising a main portion and two mounting portions at two opposite sides of the main portion;
an elongated reinforcing member arranged at a middle of a side of the side plate, two ends of the reinforcing member being respectively connected to the two mounting portions of the side plate; and
at least one resilient element compressed between the main body of the reinforcing member and the main portion of the side plate.

12. The side plate assembly of claim 11, wherein the reinforcing member comprises an elongated main body and two clasping portions at two opposite ends of the main body, the two clasping portions of the reinforcing member buckling with the two mounting portions of the side plate, respectively.

13. The side plate assembly of claim 12, wherein each of the two clasping portions comprises a leg extending from an end of the main body towards the main portion of the side plate, the leg forming a hook thereon, each of the two mounting portions defining a through hole therein, the leg of each of the two clasping portions being inserted in the through hole of a corresponding mounting portion, the hook of the leg extending through the through hole from one side of the mounting portion and abutting the other side of the mounting portion.

14. The side plate assembly of claim 13, wherein each of the two mounting portions is L-shaped, and has a flange parallel to the main portion, the through hole being defined in the flange.

15. The side plate assembly of claim 14, wherein the reinforcing member forms two positioning pieces on a lateral side of the main body respectively adjacent to the two clasping portions, the flange of each of the two mounting portions defining a positioning hole therein adjacent to the through hole, the two positioning pieces being received in the positioning holes of the two mounting portions, respectively.

16. The side plate assembly of claim 12, wherein the main body of the reinforcing member has a substantially hollow rectangular cross section, the main body having a bottom plate facing the main portion of the side plate, the at least one resilient element being integrally formed with the reinforcing member as a single monolithic piece.

17. The side plate assembly of claim 12, wherein the at least one resilient element comprises a plurality of resilient sheets arranged along a longitudinal axis of the reinforcing member and spaced from each other, each resilient sheet protruding from the bottom plate of the main body towards the main portion of the side plate.

18. The side plate assembly of claim 17, wherein each resilient sheet is curved, and has a side connected to the bottom plate of the main body.

19. The side plate assembly of claim 17, wherein the main body further has a top plate opposite to the bottom plate, each of the two clasping portions comprising a leg extending from an end of the top plate of the main body towards the main portion of the side plate, the leg forming a hook thereon, each of the two mounting portions defining a through hole therein, the leg of each of the two clasping portions being inserted in the through hole of a corresponding mounting portion, the hook of the leg extending through the through hole from one side of the mounting portion and abutting the other side of the mounting portion.
